(19) United States
(12) Patent Application Publication
(10) Pub. No.: US 2010/0149001 A1
(43) Pub. Date: Jun. 17, 2010

(54) OPERATING DIAL

(76) Inventors: Kouichi Yamanoue, Hiroshima (JP); Takeshi Yamane, Hiroshima (JP); Yoshifumi Makino, Hiroshima (JP)

Correspondence Address: FRASER CLEMENS MARTIN & MILLER LLC, 28366 KENSINGTON LANE, PERRYSBURG, OH, 43551, US

(21) Appl. No.: 12/066,895

(22) PCT Filed: Sep. 14, 2006
(86) PCT No.: PCT/JP2006/318252

§ 371 Date: Mar. 14, 2008

(30) Foreign Application Priority Data
Sep. 14, 2005 (JP) 2005-267050
Jan. 23, 2006 (JP) 2006-014045

(51) Int. Cl. H03K 17/94

(52) U.S. Cl. 341/35

(57) ABSTRACT

The present invention provides an operating dial low in cost and of superior durability and reliability with a high rotary angle detection accuracy.

An operating dial operated by rotation, comprising a printed circuit board 10 having an electric circuit; a drive electrode 13 provided on said printed circuit board 10; a plurality of detecting electrodes 12 provided around said drive electrode 13 on said printed circuit board 10; a ring electrode 101 disposed in opposition to said drive electrode 13 across a gap, such that the ring electrode 101 has at least one projection 102 projecting outward to oppose one of said plurality of detecting electrodes 12 across a gap; and a dial made of an electrically insulating material, rotatable and integral with said ring electrode 101.

### TECHNICAL FIELD

The present invention relates to an operating dial, and more particularly to a rotary operating dial desirable for use in a climate control panel or the like installed in a vehicle, whereby the absolute rotational position of the operating dial is electrically detected.

### BACKGROUND ART

Known rotary operating dials include those in which switching contacts are disposed around the circumference of the operating dial, and those in which a drive gear and a rotary switch are disposed around the circumference of the operating dial (see Patent Document 1).

Patent Document 1: JP-A-2001-184969

### DISCLOSURE OF THE INVENTION

### Problems to be Solved by the Invention

In the aforementioned conventional art there were concerns about durability and reliability over long term use in systems with switching contacts due to the occurrence of poor contact caused by infiltration of dust and the like into a vehicle interior, or by rubbing wear of the electrical contacts. Conversely, the requirement for complex dust-preventing structures and gold plating or the like of said electrical contacts as a means for improving said durability and reliability led to increased cost.

In systems having a drive gear, the need for three components to protect the drive gear—a front case, a middle case, and a rear case—led to inevitable cost increases from a structural standpoint.

As an example, when a Murata Manufacturing Co. rotary position sensor SV01 Series is used as a rotary switch, it is known that in addition to the rotary position sensor's 3% rotary detection error, there is also a rotary angular transmission error in the drive gear, leading to a detection error of approximately 5% in the operating dial rotational position as a percentage of the total rotary angle [range].

Therefore for a hypothetical total rotary angle [range] of 240° in the rotary switch operating dial, an error of 240×0.05=12° would arise. If, for example, the climate control temperature setting dial resolution is 32 steps/240°, the required angular resolution would be 7.5°. Therefore if such a rotary switch were applied to the temperature setting dial in a climate control [system], the error would be larger than the required rotary angle detection accuracy value.

The object of the present invention is to provide an operating dial low in cost and of superior durability and reliability, as well as high dial rotary angle detection accuracy.

### Means for Resolving Problem

In order to achieve the aforementioned object, the operating dial of the present invention comprises a printed circuit board (10) having an electric circuit; a drive electrode (13) provided on said printed circuit board (10); a plurality of detecting electrodes (12) provided around said drive electrode (13) on said printed circuit board (10); ring electrodes (101, 101a) disposed in opposition to said drive electrode (13) across a gap, such that the ring electrodes (101, 101a) have at least one projection (102, 102a) projecting outward to oppose one of said plurality of detecting electrodes (12) across a gap; and a dial made of an electrically insulating material, rotatable and integral with said ring electrodes (101, 101a).

Thus in the operating dial of the present invention, the drive electrode, detection electrode, and ring electrode are mutually non-contacting. There is therefore no risk of electrode wear or bad contact in the operating dial of the present invention, hence durability and reliability are excellent. Moreover, because there is no need to provide complex dust-prevention structures or gear structures for the operating dial of the present invention, its constitution can simple, and the operating dial of the present invention can therefore be manufactured at a low cost.

Furthermore, because the operating dial of the present invention does not require a gear structure, there is no error induced by a gear structure. Rather, the dial rotary angle is detected in a digital manner by detection electrodes, whose number corresponds to the dial setting resolution or number of steps, and which are disposed on a printed circuit around the outer perimeter of the dial. A high rotary angle detection accuracy is therefore achieved.

The present invention preferably comprises a drive circuit (200) for applying a high frequency signal to the driving electrode (13); a switching circuit (300) for sequentially connecting each of said plurality of detecting electrodes (12) and outputting signals from the connected detecting electrodes (12); and signal detection means (400) for processing output signals from said switching circuit (300) and detecting signals induced on the detecting electrodes (12) opposing the projections (102, 102a) on said ring electrodes (101, 101a) by using high frequency signals applied to said drive electrode (13), thereby outputting a detection signal corresponding to the dial operating position.

When a high frequency signal is applied to the drive electrode, a high frequency signal is induced on the ring electrode opposing the drive electrode. Moreover, a high frequency signal is also selectively induced on that detection electrode which, among the plurality of detection electrodes, opposes the ring electrode projection. As a result the signal level from the detection electrode opposing the projection becomes the highest among the signals from the plurality of detection electrodes. Since the projection on the ring electrode rotates integrally with the dial, the detection electrode on which the highest signal level is detected will be determined according to the rotary operational position of the dial. The operating dial operating position is thus detected by identifying the detection electrode at which the maximum signal level is detected.

In the present invention, said drive electrode (13) preferably has a circular pattern formed coaxially with said dial, and said ring electrodes (101, 101a) are disposed to overlay the circular pattern on said drive electrode (13).

Thus if the drive electrode is given a circular pattern, a high frequency will be induced on the ring electrode via the drive electrode, irrespective of the dial rotary angle.

In the present invention, said drive circuit (200) preferably has a square wave signal generating circuit and an L-C resonance circuit for extracting the frequency component of high frequency signals applied to said drive electrode (13) from the square wave signal generated by said square wave signal generating circuit.

A high frequency signal of a desired frequency can thus be applied to the drive electrode.

When dial parts and ring electrode parts are formed separately, the operating dial is assembled by hand fitting those parts. In such cases an assembly fixture is needed for assembling the operating dial. Inspection of the fitted state is also necessary, given the risk of assembly errors in the semi-fitted state. Assembly errors and the requirement for inspection of the fitted state lead to increased cost.

In the present invention said dial therefore preferably has a sleeve (100a); said sleeve (100a) having a flange (1000), the bottom surface of which opposes said drive electrode; said flange (1000) having at least one projection (1001) projecting outward; whereby said ring electrode (101a) is printed on the bottom surface of said flange (1000); and the projection (102a) on said ring electrode (101a) is printed on the bottom surface (1002) of the projection (1001) on said flange (1000).

Thus while two parts were required when the dial part and the ring electrode part were formed separately, the same function can effectively be accomplished with a single part by print forming the ring electrode. Part count can be thus be reduced and cost lowered. Furthermore, there is no need to fit and assemble the dial part and the ring electrode part, and therefore no risk of mis-assembly and no requirement for inspection of assembly errors. There is also no need to separately manufacture a ring electrode. Mold costs for ring electrode parts can thus also be dispensed with.

### EFFECTS OF THE INVENTION

The present invention thus provides an operating dial of low cost and superior durability and reliability, with a high dial rotary angle detection accuracy.

### BEST MODE FOR CARRYING OUT THE INVENTION

Below, referring to figures, we discuss embodiments of the operating dial of the present invention.

First, referring to FIG. 1, we discuss a basic structure for an embodiment of the operating dial. FIG. 1 shows the basic structure of an operating dial according to the present invention.

As shown in FIG. 1, the operating dial according to the present embodiment is an operating dial operated by rotation, comprising a printed circuit board 10 having an electric circuit; a drive electrode 13 provided on said printed circuit board 10; a plurality of detecting electrodes 12 provided around said drive electrode 13 on said printed circuit board 10; a ring electrode 101 disposed in opposition to said drive electrode 13 across a gap, such that the ring electrode 101 has at least one projection 102 projecting outward to oppose one of said plurality of detecting electrodes 12 across a gap; and a dial made of an electrically insulating material, rotatable and integral with said ring electrode 101.

The drive electrode (13) has a circular pattern formed coaxially with the dial, and the ring electrodes (101, 101a) are disposed to overlay the drive electrode 13 circular pattern. The dial has a resin sleeve 100.

The sleeve 100 has a cylindrical shape formed as an integral piece with the operating dial. The sleeve 100 is fit with the dial trunk portion 104 shown in FIG. 2, and is rotatably attached to the front surface of the printed circuit board 10. A serration 103 is disposed on the inside surface of the sleeve 100. A click force is generated corresponding to the sleeve 100 rotary position by a spring (not shown) pressing against the serration 103.

The detecting electrodes 12 are constituted by printed wiring patterns disposed on the circumference of the printed circuit board 10 surface coaxially with the sleeve 100, separated by equal angular distances. The drive electrode 13 is constituted by a circular pattern formed coaxially with the dial on the inside circumference of the detecting electrodes 12 on the printed circuit board 10.

The ring electrode 101, as shown in FIG. 2, is fit onto the bottom surface of the flange on the sleeve 100, and is disposed to overlay the drive electrode 13 circular pattern. The ring electrode 101 has a projection 102 projecting outward from the ring electrode 101. The projection 102 is disposed to be capable of opposing each detecting electrode 12. The projection 102 also has approximately the same surface area and shape as those of each of the detecting electrodes 12.

The operating dial comprises a drive circuit 200 for applying a high frequency signal to the driving electrode 13; a switching circuit 300 for sequentially connecting each of said plurality of detecting electrodes 12 and outputting signals from the connected detecting electrodes 12; and a signal detection means 400 for processing output signals from said switching circuit 300 and detecting signals induced on the detecting electrodes 12 opposing the projections 102 on said ring electrodes 101 using high frequency signals applied to said drive electrode 13, thereby outputting a detection signal corresponding to the dial operating position.

The drive electrode 13 is connected to a drive circuit 200 for supplying a high frequency signal of a predetermined frequency formed on a printed circuit board 10. Each detecting electrode 12 is electrically connected via a switching circuit 300 formed on the printed circuit board 10 to one detection electrode selected from among the plurality of detecting electrodes 12, and is also connected to the signal detection means 400.

Note that the gap D1 between the front surface of the printed circuit board 10 and the back surface of the ring electrode 101 is preferably approximately 0.2 mm. The ring electrode 101 projection 102 is constituted to be brought into opposition to one of the detecting electrodes 12 as the sleeve 100 rotates.

A static capacitance Ca is formed between the detecting electrodes 12 and the projection 102 thus constituted. A static capacitance Cb is formed between the ring electrode 101 and the drive electrode 13.

Next, FIG. 2 shows the cross-sectional structure of the operating dial of the present embodiment.

Note that diagramming of the detecting electrode 12 and drive electrode 13 patterns on the printed circuit board 10 is omitted in FIG. 2. As shown in FIG. 2, a light guide 107 formed of transparent resin material is affixed to the top surface of the printed circuit board 10. A cylindrical resin button 106, pushable from above, is inserted into the light guide 107 internal cylindrical portion.

The rotatable dial trunk portion 104 is fit onto the outer circumference of the light guide 107. The sleeve 100 and the dial trunk portion 104 are clamped in place by the bent portion of the metal plate ring electrode 101 in a state whereby the sleeve 100 is connected to the bottom portion of the dial trunk portion 104.

A pointer 105 visually indicates the dial operating position. A switch piece 108 is arranged on the surface of the printed circuit board 10 so that its electrical contacts are closed in joint movement with the pushing of the button 106. An LED 109 is packaged by soldering to the front surface of the printed circuit board 10 in order to provide nighttime illumination of the front surface of the button 106 bypassing through the light guide 107.

Next, in FIG. 3, we show examples of a climate control module structure provided with the operating dial of the present invention.

Note that in FIG. 3, as well, a graphic depiction of the detecting electrodes 12 and drive electrode 13 on the printed circuit board 10 is omitted. As shown in FIG. 3, a dial trunk portion 104, a button 106, a light guide 107, a sleeve 100, and a ring electrode 101 are inserted coaxially on the surface of the printed circuit board 10 in this climate control module. The climate control module is constituted by inserting the printed circuit board 10 from the bottom face of the case 110, affixing it to the case, then inserting a cover 111 from the back face of the case 110.

Below we discuss the operation of the operating dial of the present invention with reference to figures.

The drive circuit 200 has a square wave signal generating circuit and an L-C resonance circuit for extracting the frequency component of high frequency signals applied to said drive electrode 13 from the square wave signal generated by said square wave signal generating circuit.

The square wave signal generating circuit shown in FIG. 4 can be formed using a known R-C generating circuit. The square wave generating circuit can be set to generate, for example, a 300 KHz square wave signal. The L-C resonance circuit comprises a coil 15 and a capacitor 16. The L-C resonance circuit also performs filtering of the output from the square wave generating circuit to increase voltage amplitude and extract only desired frequencies; by this means the high frequency sign wave signal shown in FIG. 5 is supplied to a drive electrode 13 provided on the printed circuit board 10.

Using the subject resonance circuit, the voltage applied to the drive electrode 13 increases, and the high frequency component included in the output signal from the drive circuit 200 is suppressed. Interference radio waves radiated to the outside from the drive electrode 13 can thus be suppressed.

As shown in FIG. 1 and as described above, the drive electrode 13 and the ring electrode 101 circular portion oppose one another to form a static capacitance Cb. The ring electrode 101 projection 102 and the detecting electrode 12 opposing the projection 102 further form a static capacitance Ca.

Therefore the high frequency signal S1 output from the drive circuit 200 is induced on the opposing detecting electrode 12 which, among the plurality of detecting electrodes 12, opposes the ring electrode 101 projection 102. The high frequency signal S1 induced on the opposing detecting electrode 12 is sequentially selected by a switching circuit 300 comprising a known analog switch, and is input to a signal detection means 400 for amplification and detection, as shown in FIG. 4.

Note that switching circuit 300 switching signal input terminals 18 and signal detection means 400 detection signal output terminals 19 are connected to a microprocessor (not shown) to perform requisite controls.

The opposing detecting electrode 12 is selectively determined by the rotary position of the dial trunk portion 104. As an example, when the projection 102 opposes the detecting electrode 12c (see FIG. 4), the output signal S3 of the detecting circuit indicates the maximum value, while a “3” is indicated for the switching circuit switching signal S2 in FIG. 5.

The operating position of the dial trunk portion 104 is detected by identifying the detection electrode to which the switching circuit 300 is connected when the output of the signal detection means 400 is at a maximum as described above.

As explained above, the operating dial of the present invention is comprised so that the dial operating position is detected from the induction level of a high frequency signal by taking advantage of the static capacitance formed across a predetermined gap between a pattern on a printed circuit board and a rotating ring electrode. As a result, in the operating dial of the present invention there is no wear of electrodes caused by contact, and durability is excellent. Furthermore, in the operating dial of the present invention there is no detection angle error caused by the combination of a drive gear and a rotary position sensor as in the conventional art. With the operating dial of the present invention, the rotary angle can be detected digitally by the placement of detection electrodes in a number corresponding to the specified resolution; therefore the rotary position of the operating dial can be detected with high accuracy.

The operating dial of the present invention also differs from conventional art provided with driver gears in that it does not require a three layer structure of a front case, a middle case, and a rear case and can comprise, for example, only the two pieces of a cover and a case, thereby reducing cost.

In addition, the operating dial of the present invention has superior resistance to high frequency noise induced from outside. Generally speaking, the frequency of high frequency noise applied to vehicle mounted equipment is in the range of several kHz to several hundred MHz. In light of the wavelengths of such high frequency noise, the part most subject to induction of external noise in the operating dial is the ring electrode, which has the longest wire length.

However, the operating dial of the present invention detects the highest value from among signal levels coming from the plurality of detecting electrodes, and signals are selectively applied to the detection electrode by the ring electrode projections. Therefore even if a large high frequency noise is hypothetically applied to the ring electrode, the signal from the selected detection electrode will be the sum of the proper high frequency signal and the noise, which will result in a higher selected detection electrode signal level. Therefore when noise is applied, the difference between the largest signal level of the signals coming from each of the detection electrodes and the signal level of the signals from the remaining detection electrodes will increase.

As described above, the gap D1 between the ring electrode 101 and the printed circuit board 10 should be in the vicinity of 0.2 mm. However, there is a risk of condensation occurring in this gap D1 due to temperature changes or humidity in the vehicle. The places where moisture can adhere as a result of condensation are between the drive electrode 13 and the ring electrode 101, or between the ring electrode 101 projection 102 and the detecting electrode 12.

When moisture adheres in these gaps, the static capacitance Ca and Cb values increase several ten-fold. This results in an increased level of induction of high frequency signals at the detecting electrode 12. As in the case of external noise described above, adhesion of moisture causes the difference between the largest signal level of the signals coming from each of the detection electrodes and the signal level of the signals from the remaining detection electrodes to increase. Therefore as a practical matter no problem occurs even if moisture adheres due to condensation.

Note that in the present embodiment, output signals from a plurality of detecting electrodes 12 were input to a signal detection means 400 via a switching circuit 300, but when the total number of the plurality of detecting electrodes is small, the detecting electrodes and the plurality of disposed signal detection means can be directly connected, so that the output of the signal detection means is compared by a microprocessor or the like to achieve the same function. In other words, a microprocessor can serve as both the switching circuit and the signal detection means.

Next we discuss another embodiment of the operating dial of the present invention.

Note that the constitution of the present embodiment is the same as the embodiments described above except for the sleeve 100 and the ring electrode 101; a detailed description of parts which are the same is omitted.

FIG. 6(a) is a side elevation view of the sleeve on the operating dial of the present embodiment. FIG. 6(b) is a bottom view thereof. As shown in FIG. 6(a), the sleeve 100a of the present embodiment has a flange 1000. This flange 1000 has a bottom surface 1002 opposing the drive electrode 13 and a projection 1001 projecting toward the perimeter of the sleeve 100a.

Note that a diagram of the ring electrode 101a attached to the bottom surface of the flange 1000 is omitted in FIG. 6(a).

As shown in FIG. 6(b), the ring-shaped pattern of the ring electrode 101a is printed on the bottom surface 1002 of the sleeve 100a flange 1000. The ring electrode 101a projection 102a pattern is printed on the bottom surface of the flange 1000 projection 1001. The ring electrodes 101a and the projection 102a are attached to and printed on the flange by hot stamping.

A free-standing sleeve 100 on which a ring electrode is attached by printing effectively serves the same function as the assembled sleeve 100 and ring electrode 101 in the embodiment described above. Since the number of parts is reduced, cost is also lowered, and since there is no risk of mis-assembly, product reliability also improves.

Note that the method for forming a ring electrode pattern on the sleeve is not limited to the hot stamp method; hydraulic transfer or metal thin film insertion forming methods may also be used.

### INDUSTRIAL APPLICABILITY

As explained above, the operating dial of the present invention is able to accurately and in a non-contacting manner detect a dial rotary position, and provides a dial structure with high reliability with respect to external noise, condensation, and the like, making it favorable for use as a dial in automotive climate control devices as well as for general electrical products.

### BRIEF DESCRIPTION OF DRAWINGS

FIG. 1 is a diagram showing the basic structure of an operating dial in an embodiment of the present invention;

FIG. 2 is a cross-sectional view of an operating dial in an embodiment of the present invention;

FIG. 3 is an exploded perspective view showing the structure of a climate control module using the operating dial of the present invention;

FIG. 4 is an electrical circuit diagram of the operating dial in an embodiment of the present invention;

FIG. 5 is a diagram showing electrical signal waveforms explaining the operation of the operating dial in an embodiment of the present invention;

FIG. 6 (a) is a side elevation view of the sleeve in an operating dial in an embodiment of the present invention; and

FIG. 6 (b) is the bottom view of the sleeve in an operating dial in an embodiment of the present invention.

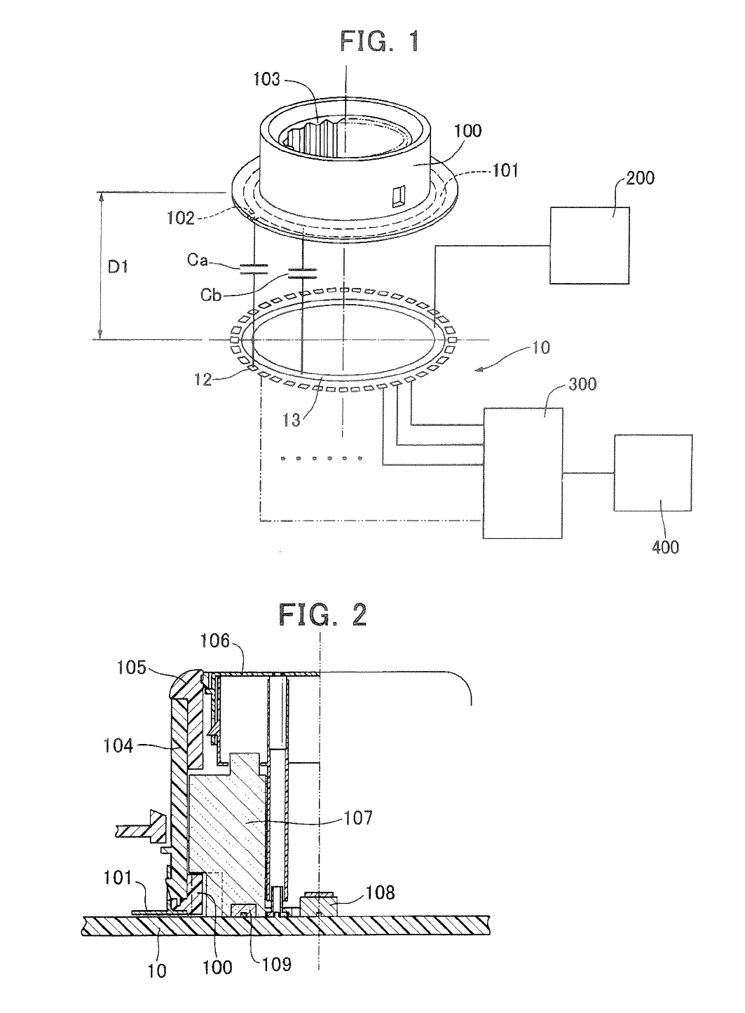

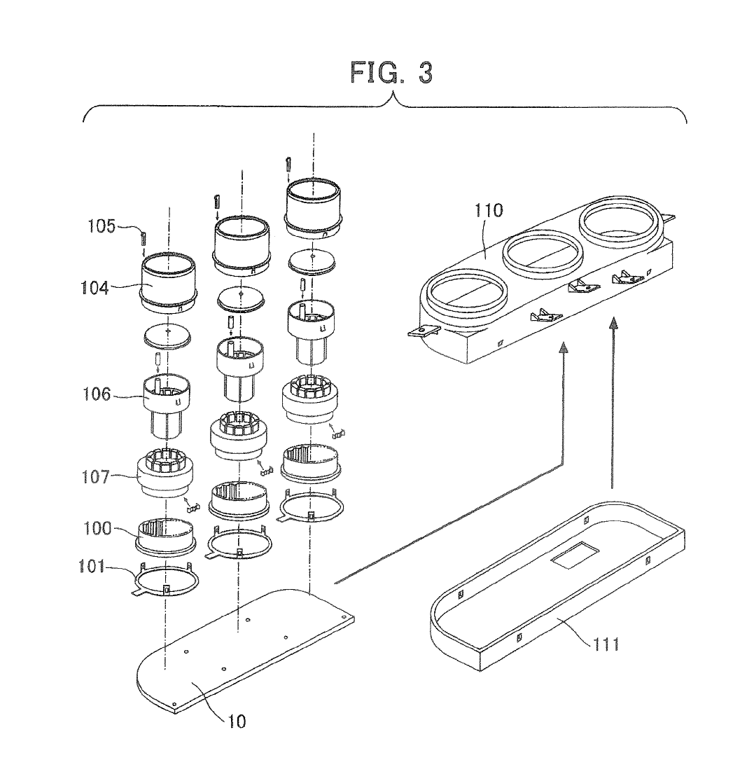

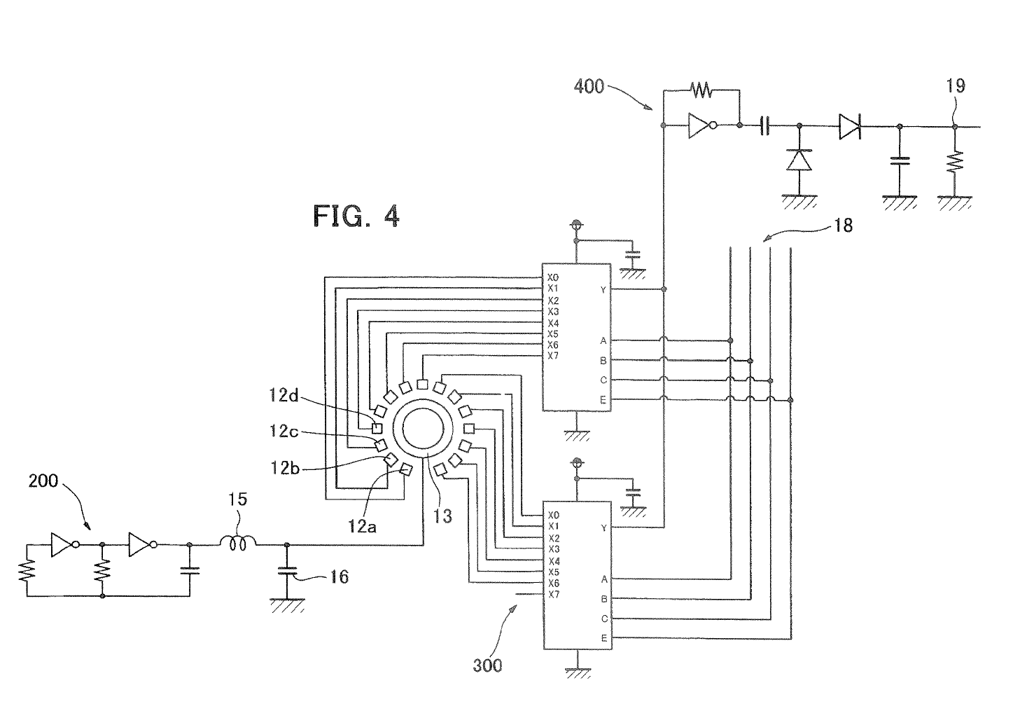

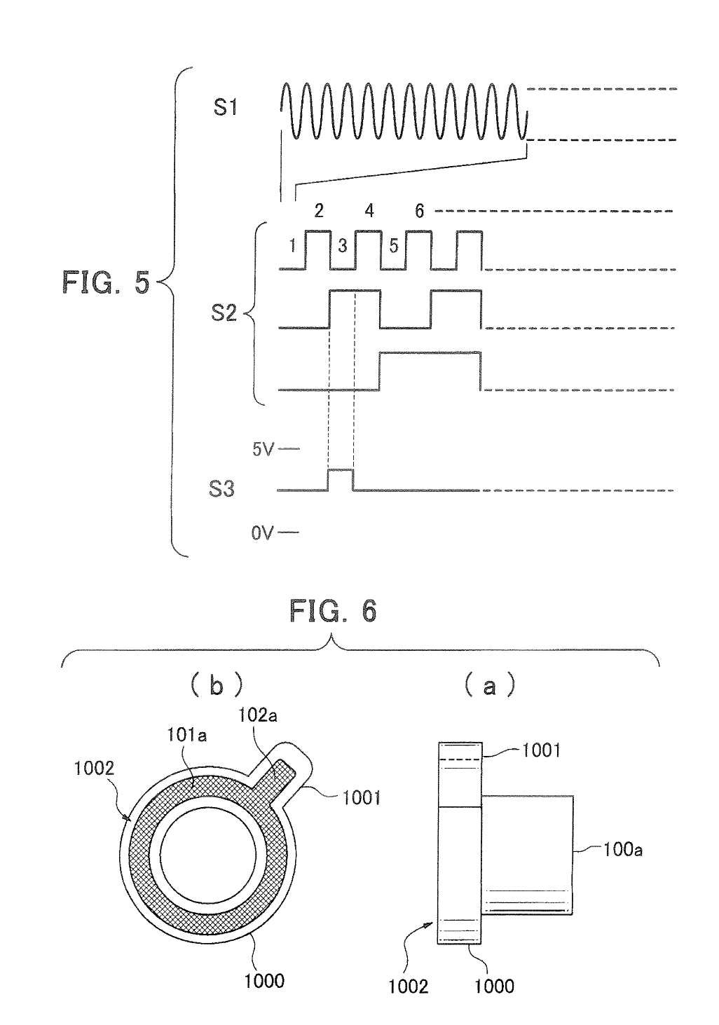

### EXPLANATION OF REFERENCE NUMERALS

10 Printed circuit board
12 Detection electrode
13 Drive electrode
15 Coil
16 Capacitor
12a-12d Detection electrodes
18 Switching signal input terminal
19 Detection signal output terminal
100, 100a Sleeve
101, 101a Ring electrode
102, 102a Projections
103 Serration
104 Dial trunk portion
105 Pointer
106 Button
107 Light guide
108 Switch
109 LED
110 Case
111 Cover
200 Drive circuit
300 Switching circuit
400 Signal detection means
1000 Flange
1001 Projection
1002 Bottom surface
Ca, Cb Static capacitance
S1 Drive circuit means output signal
S2 Switching signal
S3 Signal detection means output signal

1. An operating dial operated by rotation, comprising:
a printed circuit board (10) having an electric circuit;
a drive electrode (13) provided on said printed circuit board (10);
a plurality of detecting electrodes (12) provided around said drive electrode (13) on said printed circuit board (10);
ring electrodes (101, 101a) disposed in opposition to said drive electrode (13) across a gap, such that the ring electrodes (101, 101a) have at least one projection (102, 102a) projecting outward to oppose one of said plurality of detecting electrodes (12) across a gap;
a dial made of an electrically insulating material, rotatable and integral with said ring electrodes (101, 101a);
a drive circuit (200) for applying a high frequency signal to the driving electrode (13); a switching circuit (300) for sequentially connecting each of said plurality of detecting electrodes (12) and outputting signals from the connected detecting electrodes (12); and
signal detection means (400) for processing output signals from said switching circuit (300) and detecting signals induced on the detecting electrodes (12) opposing the projections (102, 102a) on said ring electrodes (101, 101a) by using high frequency signals applied to said drive electrode (13), thereby outputting a detection signal corresponding to the dial operating position;
wherein the drive circuit (200) includes:
a square wave signal generating circuit; and
an L-C resonance circuit for extracting the frequency component of high frequency signals applied to said drive electrode (13) from the square wave signal generated by said square wave signal generating circuit.

2. (canceled)

3. The operating dial according to claim 1, wherein said drive electrode (13) has a circular pattern formed coaxially with said dial on the printed circuit board connected to the drive circuit (200), and said ring electrodes (101, 101a) are disposed to overlay the circular pattern on said drive electrode (13).

4. (canceled)

5. The operating dial according to claim 1, wherein said operating dial detects the position of the detecting electrode connected to the switching circuit (300) as a dial operating position when the signal strength output from the signal detection means (400) indicates a maximum value.
